(19) United States
(12) Patent Application Publication
(10) Pub. No.: US 2022/0045027 A1
(43) Pub. Date: Feb. 10, 2022

(54) SEMICONDUCTOR DEVICE AND METHOD OF MANUFACTURING THE SAME

(71) Applicant: Panasonic Intellectual Property Management Co., Ltd., Osaka (JP)

(72) Inventors: SHOZO OCHI, Osaka (JP); HIDETOSHI KITAURA, Osaka (JP)

(21) Appl. No.: 17/365,044

(22) Filed: Jul. 1, 2021

(30) Foreign Application Priority Data
Aug. 4, 2020 (JP) 2020-132620

(51) Int. Cl. H01L 23/00

(52) U.S. Cl. CPC H01L 24/32; H01L 24/29; H01L 24/27; H01L 24/83; H01L 2224/8384; H01L 2224/29083; H01L 2224/29017; H01L 2224/29139; H01L 2224/27332; H01L 2224/32225

(57) ABSTRACT

A semiconductor device includes an insulation board, an electrode provided on the insulation board, a bonding layer provided on the electrode and made of a sintered body of metal particles having an average particle size of nano-order, and a semiconductor element bonded to the electrode via the bonding layer. A layer thickness of the bonding layer is greater than or equal to 220 μm and less than or equal to 700 μm.

### BACKGROUND

### 1. Technical Field

The present disclosure relates to a semiconductor device and a method of manufacturing the semiconductor device.

### 2. Description of the Related Art

An insulated gate bipolar transistor (IGBT), a metal-oxide-semiconductor field-effect transistor (MOSFET), or a vertical semiconductor element such as a diode are mounted on a semiconductor device for power conversion used for inverter control of an in-vehicle charger. Electrodes are formed by metallization on front surface and back surface of these semiconductor elements, and in a typical semiconductor device, the back surface electrodes on the back surface side of the semiconductor element and a circuit board are connected via solder bonded portion.

Since an amount of heat generated by the semiconductor element tends to increase in a bonding material used in a semiconductor device for power conversion, high heat resistance is desired. However, solder material that is lead-free and has high heat resistance is not found at present. Therefore, as a material bonding technology that replaces the solder bonding, it is being studied to apply a sinter bonding technology that utilizes a sintering phenomenon of metal particles to a semiconductor device for power conversion. A sinter bonding material used in the sinter bonding technology is formed of the metal particles and organic components. In the sinter bonding technology, bonding to a boded member is performed by a porous-shaped bonding layer formed by the sintering phenomenon of the metal particles contained in the sinter bonding material.

Generally, it is known that when a particle size of the metal particles is reduced to a nanometer size and the number of constituent atoms per particle is reduced, an effect of surface area with respect to the volume of the particles increases sharply, and the melting point and the sintering temperature are significantly reduced than those in the bulk state. Various sinter bonding technologies utilizing the low-temperature sintering of such metal nanoparticles have been reported.

In Japanese Patent Unexamined Publication NO. 2007-214340, in a bonding material in which a particle layer made of ultrafine metal particles is provided on the surface of a base material, a bonding material structure suitable for ensuring metal bonding when the base material is formed of metal, is disclosed. In Japanese Patent Unexamined Publication NO. 2012-124497, a semiconductor device in which electronic members are electrically connected to each other via a bonding layer, and the bonding layer includes an Ag matrix containing crystal grains smaller than 100 nm and a dispersed phase made of metal X dispersed in the Ag matrix and having a hardness higher than Ag, is disclosed. In Japanese Patent NO. 6632686, a semiconductor device is disclosed, which includes an insulating plate, an electrode provided on the insulating plate and having a recess portion, a bonding layer formed of a sintered body of metal particles having an average particle size of greater than or equal to 10 nm and less than or equal to 150 nm provided on the electrode, and a semiconductor element bonded to the electrode via the bonding layer, wherein the recess portion does not reach an end portion of the bonding surface between the electrode and the bonding layer.

### SUMMARY

According to an exemplary embodiment of the present disclosure, a semiconductor device includes:

an insulation board;

an electrode provided on the insulation board;

a bonding layer provided on the electrode and made of a sintered body of metal particles having an average particle size of nano-order; and

a semiconductor element bonded to the electrode via the bonding layer.

A layer thickness of the bonding layer is greater than or equal to 220 μm and less than or equal to 700 μm.

A method of manufacturing a semiconductor device according to an exemplary embodiment of the present disclosure includes:

printing a first sinter bonding material containing metal nanoparticles on an electrode bonded to an insulation board;

placing a second bonding layer made of a sintered body of metal particles having an average particle size of nano-order on the first sinter bonding material;

printing a third sinter bonding material containing metal nanoparticles on the second bonding layer;

placing a semiconductor element on the third sinter bonding material; and

sintering the first sinter bonding material and the third sinter bonding material by heating while pressurizing after the semiconductor element is placed, forming a sinter bonding layer including the second bonding layer, and then bonding the electrode and the semiconductor element via the sinter bonding layer.

### BRIEF DESCRIPTION OF THE DRAWINGS

FIG. 1 is a cross-sectional view illustrating a configuration of a semiconductor device according to an exemplary embodiment of the present disclosure;

FIG. 2 is a cross-sectional view illustrating a configuration of the semiconductor device according to the exemplary embodiment of the present disclosure;

FIG. 3 is a plan view illustrating the configuration of the semiconductor device according to the exemplary embodiment of the present disclosure;

FIG. 4A is a diagram illustrating a method of manufacturing the semiconductor device according to the exemplary embodiment of the present disclosure;

FIG. 4B is a diagram illustrating a method of manufacturing the semiconductor device according to the exemplary embodiment of the present disclosure;

FIG. 4C is a diagram illustrating a method of manufacturing the semiconductor device according to the exemplary embodiment of the present disclosure;

FIG. 4D is a diagram illustrating a method of manufacturing the semiconductor device according to the exemplary embodiment of the present disclosure;

FIG. 4E is a diagram illustrating a method of manufacturing the semiconductor device according to the exemplary embodiment of the present disclosure;

FIG. 4F is a diagram illustrating a method of manufacturing the semiconductor device according to the exemplary embodiment of the present disclosure;

FIG. 5A is a diagram illustrating a method of manufacturing a second bonding layer according to the exemplary embodiment of the present disclosure;

FIG. 5B is a diagram illustrating a method of manufacturing a second bonding layer according to the exemplary embodiment of the present disclosure;

FIG. 5C is a diagram illustrating a method of manufacturing a second bonding layer according to the exemplary embodiment of the present disclosure;

FIG. 5D is a diagram illustrating a method of manufacturing a second bonding layer according to the exemplary embodiment of the present disclosure;

FIG. 5E is a diagram illustrating a method of manufacturing a second bonding layer according to the exemplary embodiment of the present disclosure; and

FIG. 5F is a diagram illustrating a method of manufacturing a second bonding layer according to the exemplary embodiment of the present disclosure.

### DETAILED DESCRIPTION

In the semiconductor device according to an exemplary embodiment of the present disclosure, since a layer thickness of a bonding layer made of a sintered body of metal particles having an average particle size of nano-order is thicker than that in the related art, even when used in a high temperature environment, cracks that may occur in the bonding layer can be suppressed and bonding reliability can be improved.

In the semiconductor device in the related art disclosed in Japanese Patent Unexamined Publication NO. 2007-214340 and Japanese Patent Unexamined Publication NO. 2012-124497, for example, due to the thermal stress of the electrode and bonding layer of the circuit board caused by the repetition of the high temperature such as 175° C. to 300° C. and the low temperature, in some cases, the cracks occur in the bonding layer and the good bonding reliability cannot be obtained.

In the semiconductor device in the related art disclosed in Japanese Patent NO. 6632686, by intentionally generating the cracks at local locations, the stress applied to the entire bonding layer is relaxed. However, the presence of the cracks causes crack growth, and good bonding reliability may not be obtained in some cases.

The present disclosure is made to solve the problems described above, and has an object of providing a semiconductor device having good reliability of bonding layer and a method of manufacturing the semiconductor device in the sintering bonding technology using the metal nanoparticles.

As in the technologies in the related art disclosed in Japanese Patent Unexamined Publication NO. 2007-214340, Japanese Patent Unexamined Publication NO. 2012-124497, and Japanese Patent NO. 6632686, it was difficult to obtain a bonding layer of which the layer thickness is thick by simply printing the sinter bonding material containing the metal nanoparticles on the electrode and heating. This is because, if the sinter bonding material contains the metal nanoparticles, even if a metal mask is disposed on the electrode and the sinter bonding material is printed thickly as described later, when the metal mask is removed after heating, the formed bonding layer hangs outward.

In view of the above circumstances, the present inventors have performed diligent studies and completed a semiconductor device in which the layer thickness of the bonding layer is thicker than that in the related art in the sinter bonding technology using the metal nanoparticles.

Hereinafter, an exemplary embodiment of the present disclosure will be described with reference to the drawings. However, the semiconductor device in the present disclosure is not limited to the forms in the drawings, and various forms can be adopted without departing from the gist of the present disclosure. The same reference numerals will be given to the same configuration elements, and the description thereof will not be repeated.

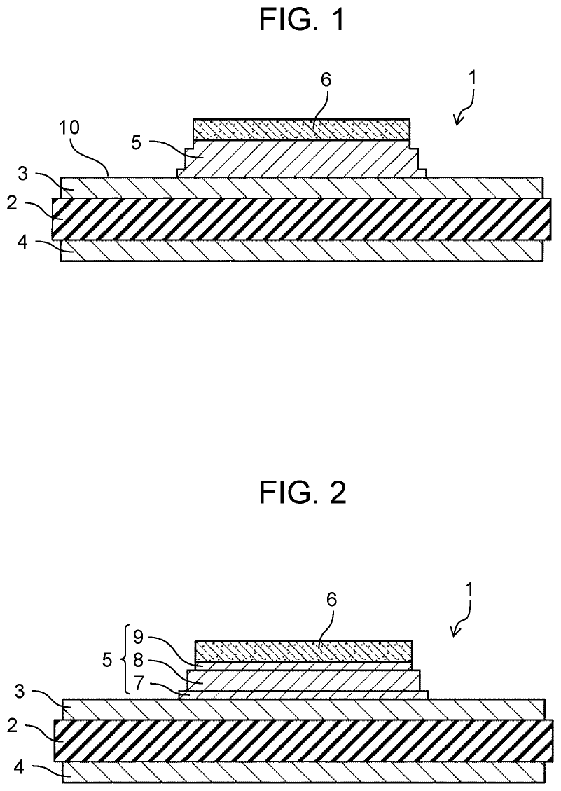

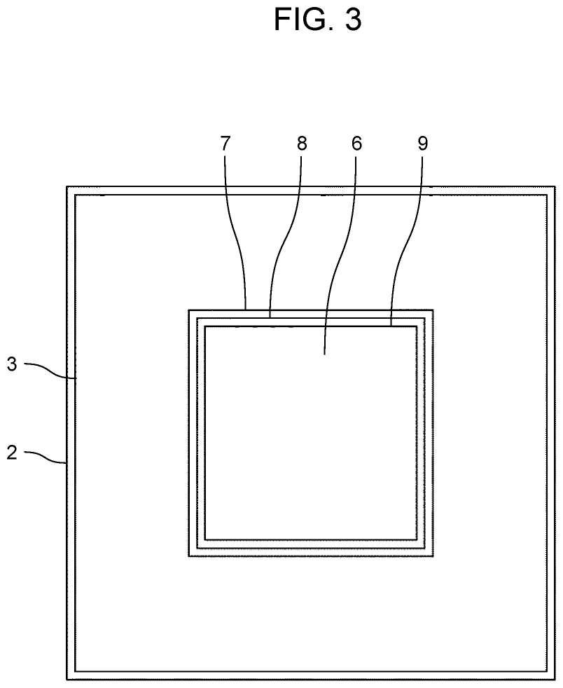

FIG. 1 and FIG. 2 are cross-sectional views illustrating a configuration of semiconductor device 1 according to the exemplary embodiment of the present disclosure. FIG. 3 is a plan view illustrating the configuration of semiconductor device 1 according to the exemplary embodiment of the present disclosure.

### 1. Configuration

As illustrated in FIG. 1 to FIG. 3, semiconductor device 1 in the exemplary embodiment of the present disclosure includes insulation board 2, electrodes 3 and 4 provided on insulation board 2, bonding layer (sinter bonding layer) 5 provided on electrode 3 and made of a sintered body of metal particles having an average particle size of nano-order, and semiconductor element 6 bonded to electrode 3 via bonding layer 5.

### 1-1. Insulation Board

Insulation board 2 supports electrode 3, electrode 4, bonding layer 5, and semiconductor element 6. As insulation board 2, not particularly limited, but a ceramic board such as silicon nitride or aluminum oxide can be used.

### 1-2. Electrode

Electrode 3 is a patterned wiring electrode. Electrode 4 is an electrode provided with a heat radiating member (not illustrated) such as a heat spreader at the bottom. Materials of electrode 3 and electrode 4 are preferably copper (Cu) and aluminum (Al). By using the materials such as copper or aluminum having excellent conductivity, the electrical characteristics of semiconductor device 1 are improved. In addition, plating treatment or sputtering treatment by any of Au, Pt, Pd, Ag, Cu, Ti and Ni may be applied on electrode 3. That is, metal layer 10 different from the metal material of electrode 3 may be provided on electrode 3, and the material of metal layer 10 may be any of Au, Pt, Pd, Ag, Cu, Ti and Ni. As a result, the bonding property between electrode 3 and bonding layer 5 is improved, and it is possible to obtain semiconductor device 1 having excellent bonding reliability even in a high temperature environment. As illustrated in FIG. 1 and FIG. 2, the electrodes may be provided on both surfaces of insulation board 2 or on any one surface of insulation board 2. Therefore, for example, electrode 4 may be omitted, and the heat radiating member (not illustrated) may be directly bonded to insulation board 2.

### 1-3. Bonding Layer

Bonding layer (sinter bonding layer) 5 bonds electrode 3 and semiconductor element 6. Bonding layer 5 is formed by sintering and bonding a plurality of metal nanoparticles by printing a sinter bonding material in which metal nanoparticles are dispersed in an organic solvent on electrode 3 heating while pressurizing. As a result, bonding layer 5 is made of a sintered body of metal particles having an average particle size of nano-order.

The material of the metal particle is preferably Ag. For example, the thermal stress between electrode 3 and bonding layer 5 caused by the repetition of high temperature such as 175 to 300° C. and low temperature can be relaxed, and thus, it is possible to obtain good bonding reliability by sintering a sinter bonding material containing Ag nanoparticles and forming a porous-shaped bonding layer.

The average particle size of the metal particles is preferably greater than or equal to 10 nm and less than or equal to 100 nm. By reducing the average particle size of the metal particles of the sintered body, a deformability of bonding layer 5 is increased, a sufficient elongation rate can be obtained even in a high temperature environment, and thus, it is possible to obtain a good bonding reliability. On the other hand, when the average particle size of the metal particles of the sintered body is excessively reduced, the sintered bond of the metal particles becomes insufficient, and thus, the bonding strength becomes insufficient. Therefore, the average particle size is preferably greater than or equal to 10 nm. In order to reduce the average particle size of the metal particles, it is necessary to reduce the average particle size of the metal nanoparticles before sintering that are contained in the sinter bonding material used. It is particularly desirable that the average particle size of the metal nanoparticles before sintering is less than or equal to 50 nm. The average particle size of the metal particles can be measured using a device having high magnification and high resolution, such as a scanning electron microscope (SEM) or a transmission electron microscope (TEM). Specifically, for example, any straight line is drawn in an SEM image or in a TEM image, each area of a plurality of metal particles to be crossed by the straight line is obtained, a circle equivalent diameter of each circle is obtained from each area, and then, the sum is calculated. Above calculation is performed for any of the five fields of view, and a total of equal to more than 200 circle-equivalent diameters are calculated. It is preferable that the average particle size of the metal particles is obtained by dividing the sum of the circle equivalent diameters in the five fields of view by the number of metal particles to be measured. Alternatively, the average particle size of the metal particles can also be measured by, for example, an electron backscatter diffraction method (EBSD). In this case, the crystalline grain boundary is defined as a crystal orientation of equal to or greater than 5°, the area of each metal particle is obtained, and then, the circle equivalent diameter is obtained from the area. It is preferable that an average value of the obtained circle equivalent diameters is the average particle size of the metal particles.

A layer thickness of bonding layer 5 is greater than or equal to 220 μm and less than or equal to 700 μm. Since the layer thickness of bonding layer 5 is greater than or equal to 220 μm, the thermal stress between electrode 3 and bonding layer 5 caused by the repetition of the high temperature such as 175° C. to 300° C. and the low temperature is relaxed, and thus, it is possible to obtain the good bonding reliability. Since the layer thickness of bonding layer 5 is less than or equal to 700 μm, the generation of air bubbles when printing the sinter bonding material or the sagging of the peripheral portion immediately after printing can be prevented, and the stable shape can be maintained, and thus, it is possible to obtain the good bonding reliability. In order to exert the above-described effects more effectively, the layer thickness of bonding layer 5 is preferably greater than or equal to 290 μm, and more preferably greater than or equal to 350 μm. The layer thickness of bonding layer 5 is preferably less than or equal to 520 μm, and more preferably less than or equal to 460 μm.

The form of bonding layer (sinter bonding layer) 5 is not particularly limited as long as the layer thickness is large and the bonding reliability can be improved. For example, in cross-sectional view, the side surface of bonding layer 5 may have a tapered shape. For example, as illustrated in FIG. 1, the side surface of bonding layer 5 may have a stair-like step in a cross-sectional view. For example, in bonding layer 5, a plurality of bonding layers may be laminated. For example, as illustrated in FIG. 2, bonding layer 5 may have a form in which a plurality of bonding layers are laminated, and the side surface of bonding layer 5 may have a stair-like step. In FIG. 2, as one exemplary embodiment of the bonding layer, bonding layer 5 includes first bonding layer 7 provided on electrode 3, second bonding layer 8 provided on first bonding layer 7, and third bonding layer 9 provided on second bonding layer 8. Semiconductor device 1 illustrated in FIG. 2 will be described in detail below.

The layer thickness of each of first bonding layer 7 and third bonding layer 9 is preferably greater than or equal to 10 μm and less than or equal to 100 μm, respectively. Since the layer thickness of each of first bonding layer 7 and third bonding layer 9 is greater than or equal to 10 μm respectively, the thermal stress between electrode 3 and bonding layer 5 caused by the repetition of the low temperature and the high temperature in use in a high temperature environment can be relaxed, and thus, it is possible to obtain the good bonding reliability. Since the layer thickness of each of first bonding layer 7 and third bonding layer 9 is less than or equal to 100 μm respectively, at the time of sintering the first sinter bonding material before sintering of first bonding layer 7 and third bonding layer 9 and the third sinter bonding material, the amount of shrinkage of the sintered body is relaxed. As a result, the stress generated between electrode 3 and bonding layer 5 can be relaxed, and a stable shape can be maintained. In order to exert the above-described effects more effectively, the layer thickness of each of first bonding layer 7 and third bonding layer 9 is more preferably greater than or equal to 40 μm, and still more preferably greater than or equal to 50 μm. The layer thickness of each of first bonding layer 7 and third bonding layer 9 is more preferably less than or equal to 70 μm, and still more preferably less than or equal to 60 μm.

The layer thickness of second bonding layer 8 is preferably greater than or equal to 200 μm and less than or equal to 500 μm. Since the layer thickness of second bonding layer is greater than or equal to 200 μm, for example, the thermal stress between the electrode and the bonding layer of the circuit board caused by the repetition of the high temperature such as 175° C. to 300° C. and the low temperature is relaxed, and thus, it is possible to obtain the good bonding reliability. Since the layer thickness of the second bonding layer is less than or equal to 500 μm, at the time of sintering the second sinter bonding material before sintering second bonding layer 8, the amount of shrinkage of the sintered body is relaxed, and thus, the stable shape can be maintained. In order to exert the above-described effects more effectively, the layer thickness of second bonding layer 8 is more preferably greater than or equal to 250 μm, and still more preferably greater than or equal to 300 μm. The layer thickness of second bonding layer 8 is more preferably less than or equal to 450 μm, and still more preferably less than or equal to 400 μm. The layer thickness of second bonding layer 8 is preferably larger than the layer thickness of each of first bonding layer 7 and third bonding layer 9. As a result, the layer thickness of bonding layer 5 can be increased and the bonding reliability can be improved.

As illustrated in FIG. 3, each of first bonding layer 7, second bonding layer 8 and third bonding layer 9 has a rectangular shape in a plan view. In FIG. 2, the shape is a square. It is preferable that the areas of first bonding layer 7, second bonding layer 8 and third bonding layer 9 in a plan view satisfy the following expression (1).

area of first bonding layer≥area of second bonding layer≥area of third bonding layer (1)

As a result, when forming second bonding layer 8 on first bonding layer 7, it is possible to suppress the protrusion due to the variation in the position accuracy and the variation in the dimensions. In addition, similarly, when forming third bonding layer 9 on second bonding layer 8, it is possible to suppress the protrusion due to the variation in the position accuracy and the variation in the dimensions.

In addition, when the above expression (1) is satisfied, as illustrated in FIG. 2, it is preferable that semiconductor device 1 has a stair-like step formed on the side surfaces of first bonding layer 7, second bonding layer 8, and third bonding layer 9. As a result, the upper layer does not protrude from the lower layer, and the layers can be more reliably laminated.

If the layers of bonding layer 5 in FIG. 2 (that is, the interface between first bonding layer 7 and second bonding layer 8 and the interface between second bonding layer 8 and third bonding layer 9) cannot be recognized, it may correspond to FIG. 1.

### 1-4. Semiconductor Element

The material of semiconductor element 6 is preferably any of silicon carbide, gallium nitride, gallium arsenide and diamond. Since semiconductor element 6 formed of these wide bandgap semiconductor materials has a higher junction temperature at the operating limit than semiconductor element formed of silicon, it can be used in a high temperature environment. The semiconductor device using the semiconductor element formed of silicon can be used only at a temperature of approximately lower than or equal to 150° C., however, semiconductor device 1 using semiconductor element 6 formed of these wide bandgap semiconductor materials can be used even at a high temperature of 250° C. to 300° C.

### 1-5. Dimensions

The size of each member described above is not particularly limited, but as a preferable example, insulation board 2 is 24 mm×24 mm×0.3 mm in thickness, electrode 3 and electrode 4 are 22 mm×22 mm×0.8 mm in thickness, respectively, first bonding layer 7 is 7 mm×7 mm×0.05 mm in thickness, second bonding layer 8 is 6 mm×6 mm×0.25 mm in thickness, third bonding layer 9 is 5 mm×5 mm×0.05 mm in thickness, semiconductor element 6 is 5 mm×5 mm×0.3 mm in thickness.

### 1-6. Action Effects

According to the exemplary embodiment of the present disclosure, in the sinter bonding technology using metal nanoparticles, it is possible to provide a semiconductor device having the bonding layer with a good reliability and a method of manufacturing the semiconductor device.

Specifically, according to the configuration described above, since the layer thickness of bonding layer 5 is thicker than that in the related art, the stress generated due to the difference in thermal expansion between electrode 3 and bonding layer 5 can be reduced and a crack that may occur in bonding layer 5 can be suppressed, and thus, it is possible to provide semiconductor device 1 with high bonding reliability. Specifically, the thermal stress between electrode 3 and bonding layer 5 caused by the repetition of the high temperature such as 175° C. to 300° C. and the low temperature can be relaxed, and thus, it is possible to obtain the good bonding reliability. As a more specific example, even if the low temperature and the high temperature are repeated between −40° C. and 200° C. for 1000 cycles, the thermal stress occurring in the bonding layer is suppressed and the occurrence of cracks is suppressed, and thus, it is possible to improve the bonding reliability.

### 2. Method of Manufacturing

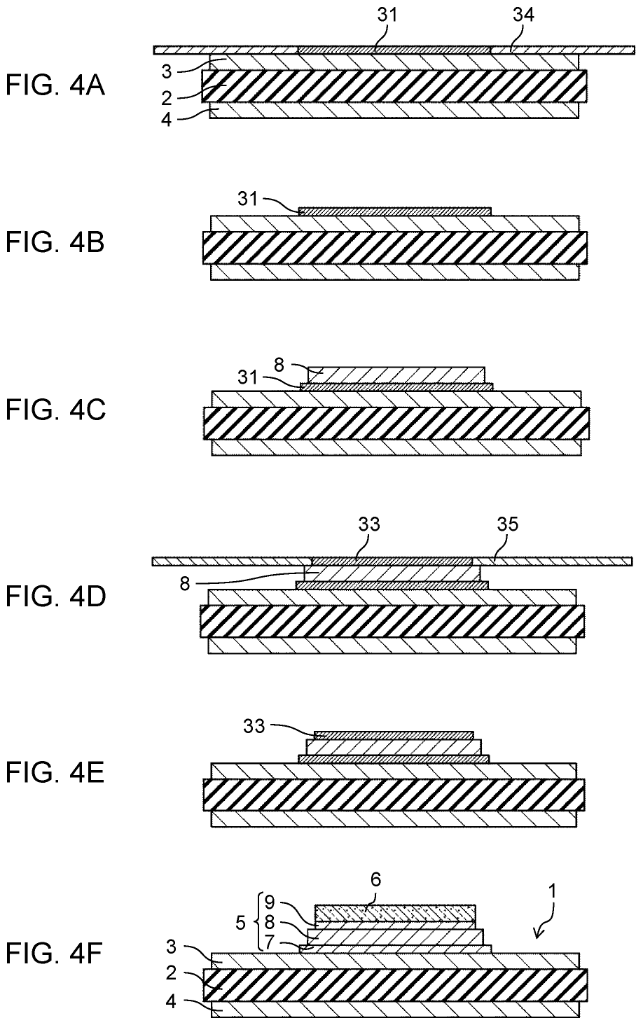

Next, a method of manufacturing semiconductor device 1 according to the exemplary embodiment of the present disclosure will be described. FIG. 4A to FIG. 4F are diagrams illustrating the method of manufacturing semiconductor device 1 according to the exemplary embodiment of the present disclosure.

First, as illustrated in FIG. 4A, a direct bonded copper (DBC) board made of insulation board 2 and electrodes 3 and electrode 4 bonded on insulation board 2 is prepared. Metal mask 34 is disposed on electrode 3 and first sinter bonding material 31 containing the metal nanoparticles is printed. The thickness of metal mask 34 is, for example, 0.1 mm.

Next, as illustrated in FIG. 4B, the solvent component of first sinter bonding material 31 is dried, and then, metal mask 34 is removed.

Next, as illustrated in FIG. 4C, second bonding layer 8 formed of a sintered body of metal particles having an average particle size of nano-order is placed on first sinter bonding material 31. A method of manufacturing second bonding layer 8 will be described later.

Next, as illustrated in FIG. 4D, metal mask 35 is disposed on second bonding layer 8 and third sinter bonding material 33 containing the metal nanoparticles is printed. The thickness of metal mask 35 is, for example, 0.1 mm.

Next, as illustrated in FIG. 4E, the solvent component of third sinter bonding material 33 is dried, and then, metal mask 35 is removed.

Next, as illustrated in FIG. 4F, semiconductor element 6 is placed on third sinter bonding material 33. Thereafter, first sinter bonding material 31 and third sinter bonding material 33 are sintered while being heated and pressurized. As a result, bonding layer (sinter bonding layer) 5 including second bonding layer 8 is formed. In FIG. 4F, first sinter bonding material 31 and third sinter bonding material 33 are sintered to form first bonding layer 7 and third bonding layer 9, respectively. As a result, first bonding layer 7, second bonding layer 8 and third bonding layer 9 are laminated to form bonding layer (sinter bonding layer) 5. At this time, first sinter bonding material 31 and third sinter bonding material 33 can be shrunk by 5% in the plane direction and by 50% in the thickness direction by sintering. As for the heating conditions, it is preferable to perform preheating at 60° C. for 30 minutes, then raise the temperature to 270° C. in 70 minutes, and hold the temperature at 270° C. for 60 minutes.

As described above, electrode 3 and semiconductor element 6 are bonded via bonding layer 5 (first bonding layer 7, second bonding layer 8 and third bonding layer 9), and then, the semiconductor device 1 is manufactured.

In FIG. 4F, semiconductor device 1 in which bonding layer 5 is laminated by a plurality of bonding layers is illustrated, however, when the layers of bonding layer 5 cannot be recognized, semiconductor device 1 as illustrated in FIG. 1 is manufactured.

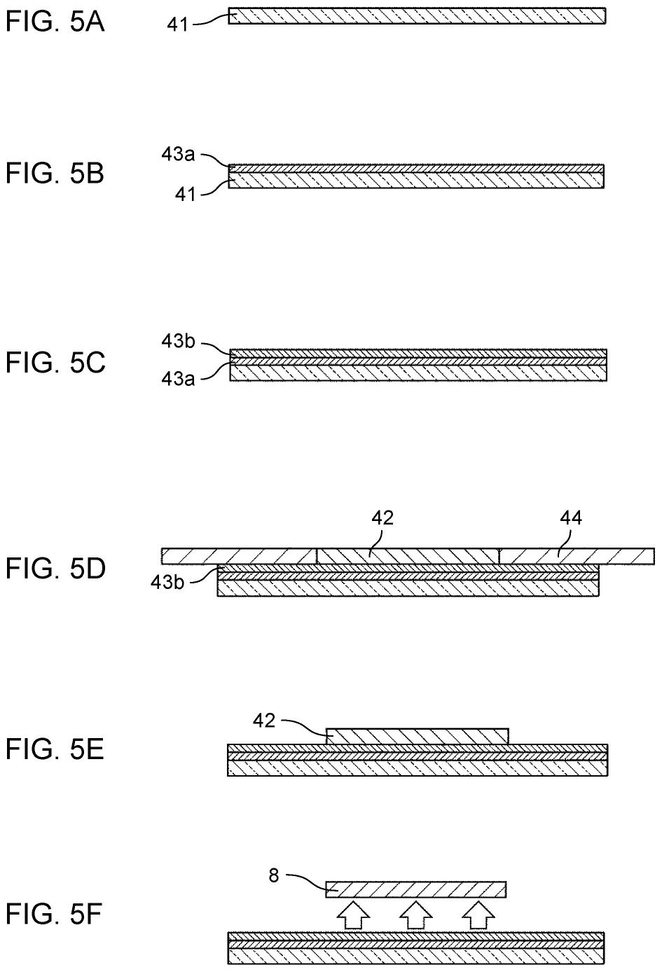

Next, a method of manufacturing second bonding layer 8 according to the exemplary embodiment of the present disclosure will be described. FIG. 5A to FIG. 5F are diagrams illustrating the method of manufacturing second bonding layer 8 according to the exemplary embodiment of the present disclosure.

First, as illustrated in FIG. 5A, support base 41 is prepared. It is preferable that support base 41 is made of glass, copper, brass or the like.

Next, as illustrated in FIG. 5B, first mold release agent 43a is spray-coated on support base 41 and dried at 100° C. for 60 minutes. It is preferable that, for example, boron nitride or the like is used as first mold release agent 43a. The thickness of first mold release agent 43a is, for example, 10 μm to 20 μm.

Next, as illustrated in FIG. 5C, second mold release agent 43b is spray-coated on first mold release agent 43a and dried at 100° C. for 60 minutes. Similarly, it is also preferable that, for example, boron nitride or the like is used as second mold release agent 43b. The total thickness of first mold release agent 43a and second mold release agent 43b is, for example, 15 μm to 30 μm. By applying the mold release agent twice as described above, gaps such as pinholes are closed, and the releasability of second bonding layer 8 is improved.

Next, as illustrated in FIG. 5D, metal mask 44 is disposed on second mold release agent 43b, and second sinter bonding material 42 containing the metal nanoparticles is printed. The thickness of metal mask 44 is, for example, 0.5 mm.

Next, as illustrated in FIG. 5E, the solvent component of second sinter bonding material 42 is dried, and then, metal mask 44 is removed.

Next, as illustrated in FIG. 5F, after forming second bonding layer 8 by heat and sintering second sinter bonding material 42, second bonding layer 8 is released from support base 41. At this time, second sinter bonding material 42 can shrink by 5% in the plane direction and 50% in the thickness direction by sintering. As for the heating conditions, it is preferable to perform preheating at 60° C. for 30 minutes, then raise the temperature to 270° C. in 70 minutes, and hold the temperature at 270° C. for 60 minutes. As described above, second bonding layer 8 is manufactured.

According to the method of manufacturing semiconductor device 1 described above, second bonding layer 8 of which the layer thickness thick is prepared in advance. First sinter bonding material 31 is printed on electrode 3 and second bonding layer 8 prepared in advance is placed on first sinter bonding material 31, and further, by printing third sinter bonding material 33 on second bonding layer 8, and after heating, bonding layer (sinter bonding layer) 5 of which the layer thickness is thick can be obtained.

As described above, in the method in the related art, it was difficult to obtain a bonding layer having a large film thickness at one time by thickly printing the sinter bonding material. In addition, when the sinter bonding material is printed thickly, it is expected that the dimensional shrinkage during sintering will increase, and the stress applied to the bonding layer will increase at this time point. According to the method of manufacturing semiconductor device 1 described above, when second bonding layer 8 is placed on first sinter bonding material 31, since second bonding layer 8 has already shrunk in dimension, the stress applied to bonding layer 5 after sintering first sinter bonding material 31 and third sinter bonding material 33 is decreased. As a result, the bonding reliability can be improved.

According to the method of manufacturing second bonding layer 8 described above, second sinter bonding material 42 shrinks during sintering, but by improving the releasability using a mold release agent, it is possible to form the bonding layer having a large film thickness without cracking due to the shrinkage.

In a semiconductor device in the present disclosure, a stress generated by a difference in thermal expansion between an electrode on a board and a bonding layer can be reduced, and a reliability of the bonding layer is improved even when used in a high temperature environment, and thus, the device can be applied to high-performance power modules used for inverter control such as in-vehicle chargers.

What is claimed is:

1. A semiconductor device comprising:
an insulation board;
an electrode provided on the insulation board;
a bonding layer provided on the electrode and made of a sintered body of metal particles having an average particle size of nano-order; and
a semiconductor element bonded to the electrode via the bonding layer,
wherein a layer thickness of the bonding layer is greater than or equal to 220 μm and less than or equal to 700 μm.

2. The semiconductor device of claim 1,
wherein a side surface of the bonding layer has a stair-like step in cross-sectional view.

3. The semiconductor device of claim 1,
wherein the bonding layer includes
a first bonding layer provided on the electrode,
a second bonding layer provided on the first bonding layer, and
a third bonding layer provided on the second bonding layer, and
a layer thickness of the second bonding layer is larger than a layer thickness of each of the first bonding layer and the third bonding layer.

4. The semiconductor device of claim 3,
wherein the layer thickness of the second bonding layer is greater than or equal to 200 μm and less than or equal to 500 μm.

5. The semiconductor device of claim 3,
wherein the layer thickness of each of the first bonding layer and the third bonding layer is greater than or equal to 10 μm and less than or equal to 100 μm.

6. The semiconductor device of claim 3,
wherein areas of the first bonding layer, the second bonding layer, and the third bonding layer in plane view satisfy the following expression,
area of first bonding layer≥area of second bonding layer≥area of third bonding layer.

7. The semiconductor device of claim 6,
wherein side surfaces of the first bonding layer, the second bonding layer, and the third bonding layer have stair-like steps in cross-sectional view.

8. The semiconductor device of claim 1,
wherein the average particle size of the metal particles is greater than or equal to 10 nm and less than or equal to 100 nm.

9. The semiconductor device of claim 1,
wherein a material of the metal particles is Ag.

10. The semiconductor device of claim 1,
wherein a material of the electrode is Cu or Al.

11. The semiconductor device of claim 1,
wherein a metal layer including a material different from a metal material of the electrode is provided on the electrode, and the material of the metal layer is any of Au, Pt, Pd, Ag, Cu, Ti and Ni.

12. The semiconductor device of claim 1,
wherein a material of the semiconductor element is any of silicon carbide, gallium nitride, gallium arsenide and diamond.

13. A method of manufacturing a semiconductor device, comprising:
printing a first sinter bonding material containing metal nanoparticles on an electrode bonded to an insulation board;
placing a second bonding layer made of a sintered body of metal particles having an average particle size of nano-order on the first sinter bonding material;
printing a third sinter bonding material containing metal nanoparticles on the second bonding layer;
placing a semiconductor element on the third sinter bonding material; and
sintering the first sinter bonding material and the third sinter bonding material by heating while pressurizing after the semiconductor element is placed, forming a sinter bonding layer including the second bonding layer, and then bonding the electrode and the semiconductor element via the sinter bonding layer.

14. The method of manufacturing the semiconductor device of claim 13,
wherein the second bonding layer is prepared in advance by a method including:
preparing a support base;
applying a first mold release agent on the support base and drying;
applying a second mold release agent on the first mold release agent and drying;
printing a second sinter bonding material containing metal nanoparticles on the second mold release agent;
forming a second bonding layer by heating and sintering the second sinter bonding material; and
releasing the second bonding layer from the support base.
